(19) United States
(12) Patent Application Publication
(10) Pub. No.: US 2024/0147698 A1
(43) Pub. Date: May 2, 2024

(54) SEMICONDUCTOR DEVICE AND METHOD OF MANUFACTURE

(71) Applicant: SAMSUNG ELECTRONICS CO., LTD., Suwon-si (KR)

(72) Inventors: Geonyeop Lee, Suwon-si (KR); Dongwook Kim, Suwon-si (KR); Yangdoo Kim, Suwon-si (KR); Sangki Nam, Suwon-si (KR); Sangwuk Park, Suwon-si (KR); Minkyu Suh, Suwon-si (KR); Dokeun Lee, Suwon-si (KR); Sungho Jang, Suwon-si (HK); Jungpyo Hong, Hong (KR)

(21) Appl. No.: 18/368,635

(22) Filed: Sep. 15, 2023

(30) Foreign Application Priority Data
Oct. 26, 2022 (KR) 10-2022-0139113

(51) Int. Cl. H10B 12/00

(52) U.S. Cl. CPC H10B 12/315; H10B 12/0335

(57) ABSTRACT

A semiconductor device includes; a lower structure, lower electrodes on the lower structure, wherein each lower electrode includes a first lower electrode and a second lower electrode on the first lower electrode and electrically connected to the first lower electrode, an upper electrode covering the lower electrodes, and a dielectric film between the lower electrodes and the upper electrode, wherein the first lower electrode includes a pillar portion and a protruding portion on the pillar portion, wherein protruding portion has a complex shape that contacts the second lower electrode.

### CROSS-REFERENCE TO RELATED APPLICATION

This U.S. non-provisional patent application claims priority under 35 U.S.C. § 119 to Korean Patent Application No. 10-2022-0139113 filed on Oct. 26, 2022 in the Korean Intellectual Property Office, the subject matter of which is hereby incorporated by reference in its entirety.

### BACKGROUND

The inventive concept relates to semiconductor devices and method of manufacturing same.

Continuing advances in electronics enable miniaturization of high-performance devices in response to end user demands. Accordingly, constituent semiconductor devices are required to be increasingly integrated, yet provide high performance functionality.

Dynamic Random Access Memory (RAM) (DRAM) is a type of volatile semiconductor memory. DRAM memory cells generally include a capacitor which must provide excellent electrical characteristics and yet facilitate continuing integration efforts.

### SUMMARY

Embodiments of the inventive concept provide semiconductor devices characterized by excellent electrical performance and improved productivity capabilities.

According to an aspect of the inventive concept, a semiconductor device may include: a lower structure, lower electrodes on the lower structure, wherein each lower electrode includes a first lower electrode and a second lower electrode on the first lower electrode and electrically connected to the first lower electrode, an upper electrode covering the lower electrodes, and a dielectric film between the lower electrodes and the upper electrode, wherein the first lower electrode includes a pillar portion and a protruding portion on the pillar portion, wherein protruding portion has a complex shape that contacts the second lower electrode.

According to an aspect of the inventive concept, a semiconductor device may include: a lower structure including a transistor, and an upper structure on the lower structure and electrically connected to the transistor. The upper structure may include; a first lower electrode on the lower structure and a second lower electrode on the first lower electrode, an upper electrode laterally separated from the first lower electrode by a dielectric layer, and a first support layer extending horizontally through the upper electrode to contact a side surface of the first lower electrode, wherein the first lower electrode includes a pillar portion and a protruding portion on the pillar portion, wherein protruding portion has a complex shape that contacts the second lower electrode.

According to an aspect of the inventive concept, a semiconductor device may include: a lower structure, lower electrodes on the lower structure, wherein each lower electrode includes a first lower electrode and a second lower electrode on the first lower electrode and electrically connected to the first lower electrode, an upper electrode on the lower structure, an etch stop layer extending horizontally to contact the lower electrodes, and a dielectric film between the lower electrodes and the upper electrode, wherein the first lower electrode includes a pillar portion and a protruding portion on the pillar portion and integrally connected to the pillar portion, the protruding portion has an inclined side surface, and the etch stop layer contacts at least a portion of the inclined side surface of the protruding portion.

According to an aspect of the inventive concept, a method of manufacturing a semiconductor device may include; forming a lower structure including a transistor, forming a stack structure by alternately stacking lower molded layers and preliminary support layers on the lower structure, forming a first lower electrode passing through the stack structure, forming a protruding portion having a complex shape at an upper portion of the first lower electrode, forming an upper molded layer on the stack structure, and forming a second lower electrode passing through the upper molded layer and contacting the protruding portion of the first lower electrode.

### BRIEF DESCRIPTION OF DRAWINGS

Advantages, benefits, and features, as well as the making and use of the inventive concept may be better understood upon consideration of the following detailed description together with the accompanying drawings, in which:

FIG. 1 is a plan (or top-down) view illustrating a semiconductor device according to embodiments of the inventive concept;

FIG. 2 is a cross-sectional view taken along line I-I′ in FIG. 1;

FIGS. 3, 4A, 4B, 5, 6, and 7 are respective, enlarged cross-sectional views illustrating possible variations of region ‘A’ indicated in FIG. 2;

FIGS. 8A, 8B, 8C, 9 and 10 respective cross-sectional views of a semiconductor device according to embodiments of the inventive concept taken along line I-I′ of FIG. 1;

FIGS. 11A, 11B, 11C, 11D, 11E, 11F, 11G, and 11H (hereafter collectively, “FIGS. 11A to 11H”) are related cross-sectional views illustrating in one example a method of manufacturing a semiconductor device according to embodiments of the inventive concept;

FIGS. 12A, 12B, 12C, 12D, 12E, and 12F (hereafter collectively, “FIGS. 12A to 12F) are related cross-sectional views illustrating in another example a method of manufacturing a semiconductor device according to embodiments of the inventive concept;

FIG. 13 is a plan view illustrating a semiconductor device according to embodiments of the inventive concept; and

FIG. 14 is a cross-sectional view illustrating a semiconductor device according to embodiments of the inventive concept.

### DETAILED DESCRIPTION

Throughout the written description and drawings, like reference numbers and labels are used to denote like or similar elements, components, features and/or method steps. Throughout the written description certain geometric terms may be used to highlight relative relationships between elements, components and/or features with respect to certain embodiments of the inventive concept. Those skilled in the art will recognize that such geometric terms are relative in nature, arbitrary in descriptive relationship(s) and/or directed to aspect(s) of the illustrated embodiments. Geometric terms may include, for example: height/width; vertical/horizontal; top/bottom; higher/lower; closer/farther; thicker/thinner; proximate/distant; above/below; under/over; upper/lower; center/side; surrounding; overlay/underlay; etc.

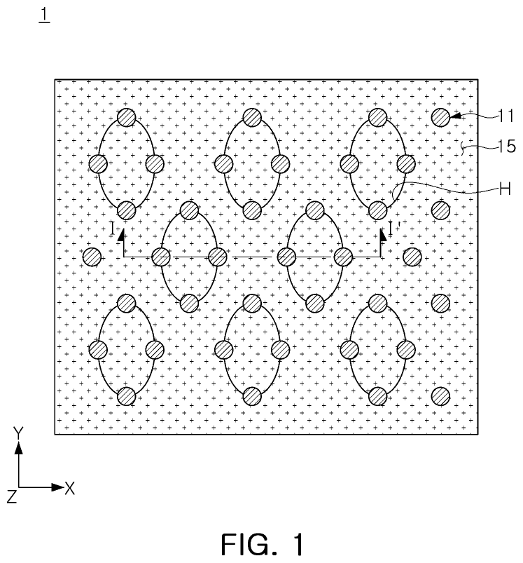

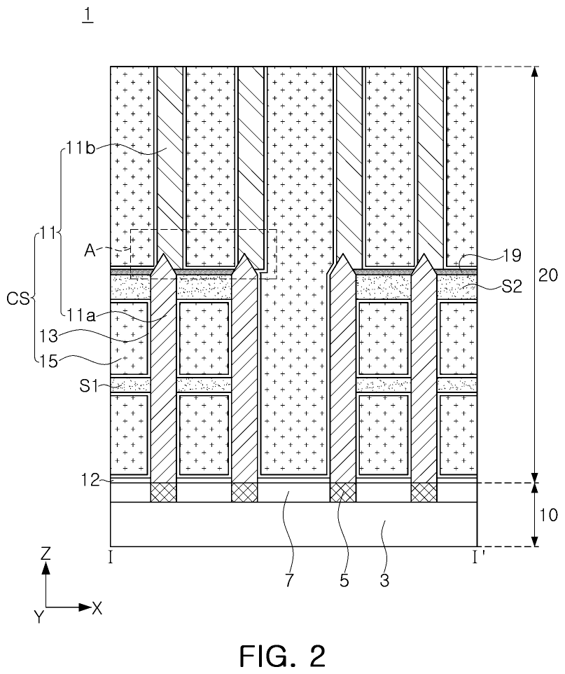

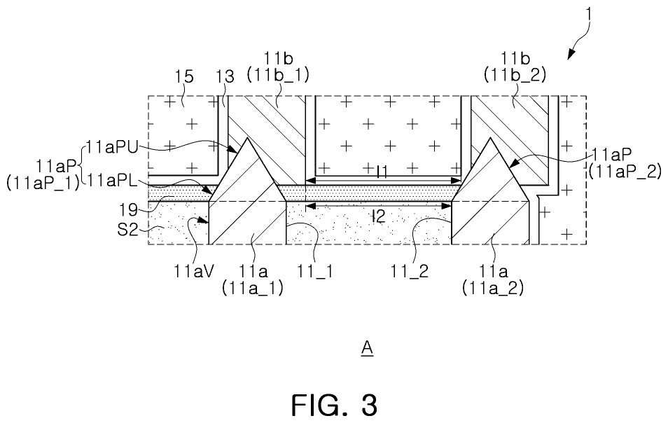

Figure (FIG. 1 is a plan view of a semiconductor device 1 according to embodiments of the inventive concept; FIG. 2 is a cross-sectional view of the semiconductor device 1 taken along line I-I′ of FIG. 1; and FIG. 3 is an enlarged cross-sectional view, in part, of region ‘A’ indicated in FIG. 2.

Referring collectively to FIGS. 1, 2 and 3, the semiconductor device 1 may include a lower structure 10 including transistors, and an upper structure 20 disposed on the lower structure 10 and including information storage structures. The semiconductor device 1 may be an assembly of memory elements including at least one transistor and at least one information storage structure (e.g., at least one capacitor). However, those skilled in art will appreciate that the number of transistors and/or the number of information storage structures associated with each memory element may vary by design. In some embodiments, the memory elements may be associated with a DRAM or a ferroelectric memory (FeRAM).

In some embodiments, the lower structure 10 may include a circuit structure 3 including the transistors, landing pads 5 on the circuit structure 3 and electrically connected to the circuit structure 3, and a lower insulating layer 7 on the circuit structure 3 and covering side surfaces of the landing pads 5. Here, the landing pads 5 may be variously arranged in relation to at least some of a plurality of lower electrodes 11. The landing pads 5 may include at least one of a semiconductor material such as polycrystalline silicon, a metal-semiconductor compound, a metal nitride film, and a metal.

In some embodiments, the upper structure 20 may include a buffer layer 12 on the lower structure 10, a capacitor structure CS, at least one support layer (S1 and S2), and an etch stop layer 19.

The buffer layer 12, having a substantially uniform thickness (e.g., a dimension measured in a vertical direction), may be disposed on the lower structure 10, and may selectively expose at least respective upper surfaces of the landing pads 5. The buffer layer 12 may include at least one insulating material such as silicon oxide, silicon nitride, and silicon oxynitride.

The capacitor structure CS may include the lower electrodes 11, a dielectric film 13, and upper electrodes 15.

The lower electrodes 11 may be respectively spaced apart (e.g., in a zigzag pattern). The lower electrodes 11 may have a pillar shape, a cylindrical shape, etc. Each lower electrode 11 may extend through (or penetrate) the buffer layer 12 in order to electrically connect a corresponding landing pad 5.

The lower electrodes 11 may include at least one conductive material, such as a semiconductor material (e.g., doped polycrystalline silicon), a metal nitride (e.g., titanium nitride (TiN)), and a metal (e.g., titanium (Ti), cobalt (Co), nickel (Ni), tungsten (W), molybdenum (Mo), etc.). For example, in some embodiments, the conductive material may include titanium nitride (TiN).

In the illustrated example of FIG. 2, each of the lower electrodes 11 includes a first lower electrode 11a and a second lower electrode 11b on the first lower electrode 11a. That is, the second lower electrode 11b may be disposed on the first lower electrode 11a and may be electrically connected to the first lower electrode 11a. Accordingly, each of the lower electrodes 11 shown in FIG. 1 may be a planar portion of a corresponding second lower electrode 11b. Each of the lower electrodes 11 may have a double pillar storage node structure including corresponding first and second lower electrodes 11a and 11b (e.g., a multi-pillar storage node structure). This configuration allows semiconductor devices according to embodiments of the inventive concept to be realized with increased integration density. Here, a multi-pillar storage node structure may include three or more lower electrodes.

Referring to FIG. 3, the first lower electrode 11a may include a pillar portion 11aV and a protruding portion 11aP on the pillar portion 11aV and integrally connected to the pillar portion 11aV. Thus, the term “pillar portion” 11aV denotes a pillar-shaped portion vertically extending in a direction substantially perpendicular to an upper surface of the lower structure 10 (e.g., a Z direction). In some embodiments, the pillar portion 11aV may have a substantially uniform width (e.g., a dimension measured in an X direction). The pillar portion 11aV may be formed with a lateral cross-section having a quadrilateral shape, a circular shape, or an elliptical shape.

The protruding portion 11aP may be disposed on an upper end portion of the first lower electrode 11a and may have a substantially pointed pyramidal shape. In this regard, the pointed pyramidal shape may be defined by a lower base portion having substantially the same width as the pillar portion 11aV and an upper point, wherein the width of the protruding portion 11aP gradually decreases in a linear manner as a function of height away from the lower base portion to the upper point. Accordingly, in some embodiments the protruding portion 11aP may have a substantially flat, inclined side surface. That is, in some embodiments, the protruding portion 11aP may have a pointed pyramidal shape characterized by side surfaces having a constant (or linear) slope.

Thus, in the illustrated example of FIGS. 1, 2 and 3, an upper surface of the first lower electrode 11a may be understood as having a relatively “complex” surface (e.g., the pointed pyramidal shape), as compared with a relatively “simple” surface (e.g., a flat planar surface). In this regard, at least a portion of the upper surface of the first lower electrode 11a may contact the second lower electrode 11b. And since the upper surface of the first lower electrode 11a is relatively complex, a corresponding contact area between the first lower electrode 11a and the second lower electrode 11b may be notably increased, as compared with a contact area provided by a relatively simply upper surface. As a result, semiconductor devices consistent with embodiments of the inventive concept exhibit improved electrical characteristics, because a contact resistance between the first and second lower electrodes 11a and 11b is reduced by the use of the complex (e.g., three-dimensionally defined) protruding portion 11aP that provides an increased contact area.

In some embodiments, the second lower electrode 11b may also have a vertical pillar structure characterized by a substantially uniform width. Here, the vertical pillar structure may be further characterized by a lateral cross-section having a triangular, quadrilateral, circular, or elliptical shape. In some embodiments, the width and/or cross-sectional shape of the second lower electrode 11b may be substantially the same as the width and/or cross-sectional shape of the first lower electrode 11a.

Further, the second lower electrode 11b may include at least one conductive material similar to that of a material included in the first lower electrode 11a. Since the second lower electrode 11b may be formed using a process separate from a process used to form the first lower electrode 11a, a material(s) boundary between the first lower electrode 11a and the second lower electrode 11b may be apparent, even if the same conductive material(s) are used to form the first lower electrode 11a and the second lower electrode 11b. For example, this boundary may be defined by a fine, intervening oxide layer, different grain sizes, etc.

The at least one support layer (e.g., S1 and S2) (hereafter regardless of number or specific disposition, “the support layers”) may be disposed within the capacitor structure CS. In this regard, respective support layers may be vertically spaced apart and variously disposed to extend in a horizontal direction (e.g., the X direction and/or the Y direction). The support layers may variously contact the lower electrodes 11. For example, one support layer (e.g., S1 or S2) may extend between respective sidewalls of two, adjacent lower electrodes 11. Upper surface(s), lower surface(s) and/or side surface(s) of one or more support layers may be substantially covered by the dielectric film 13. Further in this regard, the support layers (e.g., S1 and S2) may serve as structure(s) laterally supporting one or more lower electrodes 11, noting here that each lower electrode 11 extends vertically with a relatively high aspect ratio.

The support layers may include at least one insulating material, such as for example; silicon oxide, silicon nitride, and silicon oxynitride. More particularly, in some embodiments, the support layers may include silicon nitride (SiN) and/or silicon carbonitride (SiCN).

Assuming the use of multiple support layers (e.g., S1 and S2) in certain embodiments, a second support layer S2 may be vertically stacked on (or above) a first support layer S1, wherein a first thickness of the first support layer S1 is different from, or the same as, a second thickness of the second support layer S2. However, those skilled in the art will appreciate that the number, thickness, and arrangement of support layer(s) within embodiments of the inventive concept may vary by design.

In some embodiments, one support layer (e.g., S1) among the support layers may contact a first lower electrode 11a at a first level, and another support layer (e.g., S2) among the support layers may contact the first lower electrode 11a at a second level, different from the first level. (Here, the term “level” denotes a location or disposition in relation to an arbitrarily selected reference. Respective levels may be measured in the vertical direction). In some embodiments, an uppermost support layer (e.g., S2) among the support layers may contact an upper end portion of the pillar portion 11aV of the first lower electrode 11a.

The etch stop layer 19 may be disposed on the uppermost support layer (e.g., S2). That is, the etch stop layer 19 may extend horizontally across an upper surface of the second support layer S2. Here, the etch stop layer 19 may have a conformal thickness.

The etch stop layer 19 may include at least one of for example, silicon nitride (SiN), silicon carbonitride (SiCN), and silicon boronitride (SiBN). The etch stop layer 19 may include at least one material different from material(s) included in the support layers. Alternately or additionally, at least one material may be common to both support layers and the etch stop layer 19. In some embodiments, the etch stop layer 19 may have a thickness less than a thickness of the support layers.

In some embodiments, the etch stop layer 19 may substantially surround the side surface of the protruding portion 11aP of the first lower electrode 11a. That is, the etch stop layer 19 may contact at least a portion of the side surface of the protruding portion 11aP. The etch stop layer 19 may expose an upper region 11aPU of the protruding portion 11aP while surrounding a lower region 11aPL of the protruding portion 11aP. The upper region 11aPU of the protruding portion 11aP may include a portion contacting the second lower electrode 11b.

A lower surface of the second lower electrode 11b may be at least partially covered by (e.g., contacted by) the protruding portion 11aP of the first lower electrode 11a and the etch stop layer 19. The etch stop layer 19, together with the protruding portion 11aP, may serve as an etch stop layer during an etching process used to form an upper via hole corresponding to the second lower electrode 11b. The lower surface of the second lower electrode 11b may contact the etch stop layer 19. In contrast to the embodiments illustrated in FIGS. 2 and 3, the etch stop layer 19 may include a recess (e.g., a void formed by partial removal of the etch stop layer 19 during the formation of the upper via hole). However, even in such cases, a lower end of the second lower electrode 11b may be disposed at a level higher than that of the pillar portion 11aV.

The second lower electrode 11b may include a portion that does not vertically overlap the first lower electrode 11a. In some embodiments, a vertical central axis of the first lower electrode 11a may be the same as a vertical central axis of the pillar portion 11aV and/or a vertical central axis of the protruding portion 11aP.

However, a vertical central axis of the second lower electrode 11b may be misaligned with the vertical central axis of the first lower electrode 11a. That is, the vertical central axis of the second lower electrode 11b may be laterally shifted from the vertical central axis of the protruding portion 11aP. However, the misaligned vertical central axis of the second lower electrode 11b may contact the vertical central axis of the first lower electrode 11a on the etch stop layer 19. This outcome may occur as the first and second lower electrodes 11a and 11b are formed by separate processes.

In some embodiments, the second lower electrode 11b may be misaligned with, and yet contact the first lower electrode 11a, such that a contact area of the second lower electrode 11b with the first lower electrode 11a is reduced. However, the complex (e.g., three-dimensionally defined) nature of the protruding portion 11aP may mitigate the reduction in contact area.

In addition, by including the protruding portion 11aP, a process margin distance (e.g., a horizontal distance between adjacent electrodes) may be secured to provide a semiconductor devices exhibiting improved productivity characteristics. That is, referring to FIG. 3, given a structure wherein either or both of the first and second lower electrodes 11a and 11b are misaligned, a sufficient process margin distance may be preserved due to the presence of the complex protruding portion 11aP.

Referring to FIG. 3, the lower electrodes 11 may include a first electrode 11_1 including a first lower electrode 11a_1 and a second lower electrode 11b_1, and a second electrode 11_2 including a first lower electrode 11a_2 and a second lower electrode 11b_2. A lower end portion of the second lower electrode 11b_1 of the first electrode 11_1 may be disposed at a first level adjacent to an upper surface of the etch stop layer 19 by the protruding portion 11aP_1 of the first electrode 11_1 and the etch stop layer 19. At the first level, a first process margin distance 11 for forming the second lower electrode 11b_1 of the first electrode 11_1 may be defined as a distance from the second lower electrode 11b_1 of the first electrode 11_1 to a protruding portion 11aP_2 of the second electrode 11_2. When the protruding portion 11aP is omitted, a lower end portion of the second lower electrode 11b_1 of the first electrode 11_1 may pass through the etch stop layer 19 to contact the first lower electrode 11a_1, and may be disposed at a second level adjacent to a lower surface of the etch stop layer 19. At the second level, a second process margin distance 12 for forming the second lower electrode 11b_1 of the first electrode 11_1 may be defined as a distance from the second lower electrode 11b_1 of the first electrode 11_1 to the first lower electrode 11a_2 of the second electrode 11_2. The first process margin distance 11 may be longer than the second process margin distance 12. Consistent with this example, as a process margin distance between adjacent lower electrodes 11 relatively increases using the structure of the lower electrode 11 including the protruding portion 11aP, semiconductor device according to embodiments of the inventive concept will exhibit improved productivity.

As the thickness of the etch stop layer 19 increases, the process margin distance may increase. As the thickness of the etch stop layer 19 increases, a size of the lower region 11aPL surrounded by the etch stop layer 19 may increase, and a size of the upper region 11aPU contacting the second lower electrode 11b may decrease. Therefore, by adjusting the thickness of the etch stop layer 19, semiconductor devices according to embodiments of the inventive concept may optimize a process margin distance and/or a contact area between electrodes.

In addition, as the first lower electrode 11a includes the protruding portion 11aP, it better prevents an electric field from being misaligned and concentrated at a corner of the first lower electrode 11a. This result tends to improve overall reliability of semiconductor devices according to embodiments of the inventive concept, and may be result because an electric field between misaligned first and second lower electrodes 11a and 11b is dispersed by the complex (e.g., conically shaped) protruding portion 11aP.

Within the upper structure 20, the dielectric film 13 may cover the buffer layer 12, the lower electrodes 11, the support layers, and the etch stop layer 19. The dielectric film 13 may conformally cover upper and side surfaces of the lower electrodes 11, an upper surface of the buffer layer 12, as well as exposed surfaces of the support layers. In addition, the dielectric film 13 may conformally cover the upper surface of the etch stop layer 19. The dielectric film 13 may extend between the upper electrode 15 and the support layers.

In some embodiments, the dielectric film 13 may include at least one of for example; an oxide, a nitride, a silicide, an oxynitride, and a silicide oxynitride, including at least one of hafnium (Hf), aluminum (Al), zirconium (Zr), or lanthanum (La).

The upper electrode 15 may substantially cover the lower electrodes 11, the support layers, the etch stop layer 19, and the dielectric film 13. For example, the upper electrode 15 may fill space(s) between the lower electrodes 11, and space(s) between the support layers.

The upper electrode 15 may include at least one conductive material such as for example; doped polycrystalline silicon, a metal nitride such as titanium nitride (TiN) or the like, and a metal such as titanium (Ti), cobalt (Co), nickel (Ni), tungsten (W), molybdenum (Mo). In some embodiments, the upper electrode 15 may include silicon germanium (SiGe).

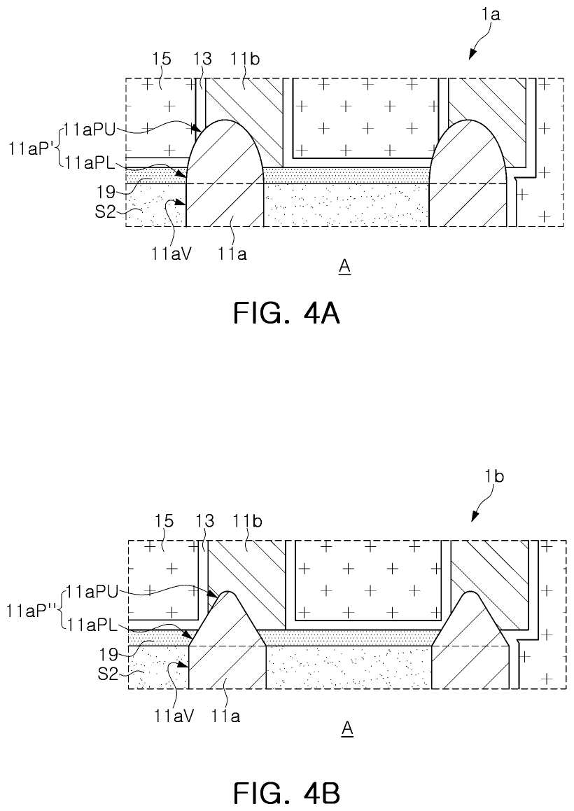

Exemplary modifications to the semiconductor device 1 of FIGS. 1, 2 and 3 will hereafter be described in relation to FIGS. 4A, 4B, 5, 6 and 7.

FIGS. 4A and 4B are respective, enlarged cross-sectional views illustrating possible variations to region ‘A’ indicated in FIG. 2 according to embodiments of the inventive concept.

Referring to FIG. 4A, a semiconductor device 1a may include a protruding portion 11aP′ having one shape different from that of FIG. 3. Here, the protruding portion 11aP′ may have a conical shape characterized by a width that varies with height. That is, the “fully conical shape” shown in FIG. 4A is characterized by a slope that gradually changes along its entire variation in height. Consistent with this characteristic, the fully conical shape may yield be a fully convex (e.g., substantially hemispheric) shape. Alternately, however, the full conical shape may be inverted in relation to the illustrated example of FIG. 4A to thereby yield fully concave shape.

Referring to FIG. 4B, a semiconductor device 1b may include a protruding portion 11aP″ having another shape different from that of FIG. 3. Here, the protruding portion 11aP″ may have a “partially conical shape” that may be understood as a hybrid between the pointed pyramidal shape of FIG. 3 and the fully conical shape of FIG. 4A. Of principle note, the partial conical shape includes a rounded upper point distinct from the pointed upper point of FIG. 3.

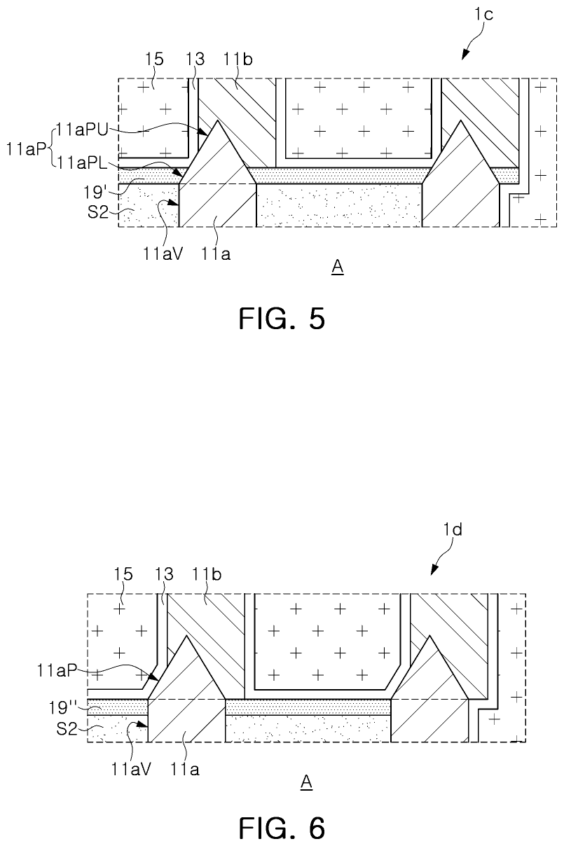

Referring to FIG. 5, within a semiconductor device 1c, the lower surface of the second lower electrode 11b may not contact the dielectric film 13. That is, the lower surface of the second lower electrode 11b may contact only the protruding portion 11aP and the etch stop layer 19′. In some embodiments, the etch stop layer 19′ may entirely surround a lower region 11aPL of the protruding portion 11aP.

Referring to FIG. 6, within a semiconductor device 1d, the etch stop layer 19″ may be disposed at a lower level than the protruding portion 11aP. Thus, the etch stop layer 19″ may contact a pillar portion 11aV while surrounding the pillar portion 11aV. Here, the etch stop layer 19″ may entirely expose the protruding portion 11aP, and the protruding portion 11aP may contact a second lower electrode 11b and/or a dielectric film 13. This structure may result if the etch stop layer 19″ is formed before forming the protruding portion 11aP.

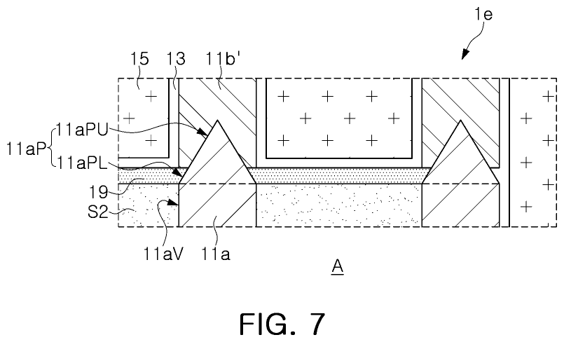

Referring to FIG. 7, within a semiconductor device 1e, the second lower electrode 11b′ may contact the first lower electrode 11a without vertical misalignment. That is, a central axis (e.g., a conceptual vertical plane) of the first lower electrode 11a may be disposed in substantially the same lateral position as a central axis of the second lower electrode 11b′.

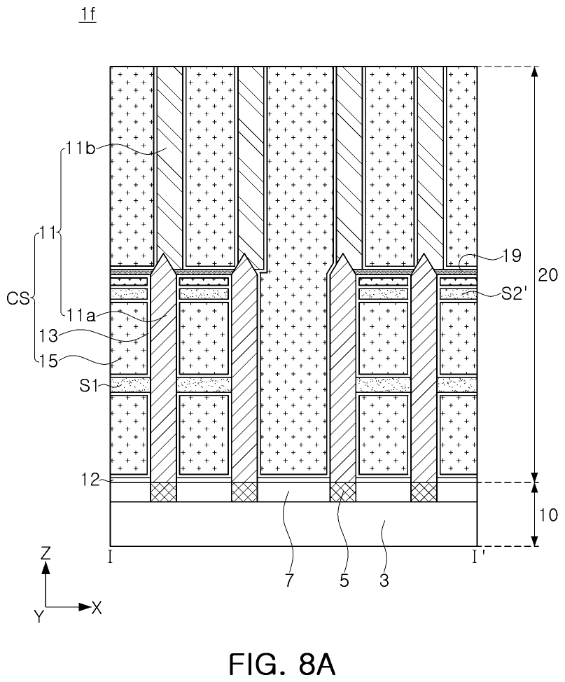

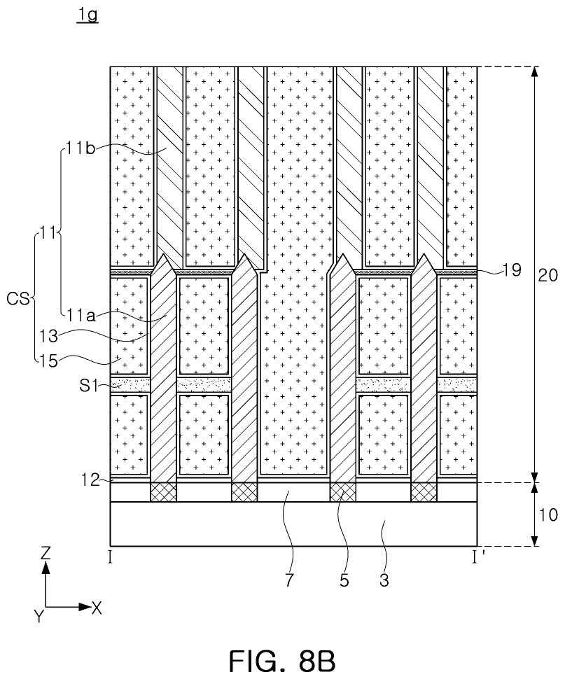

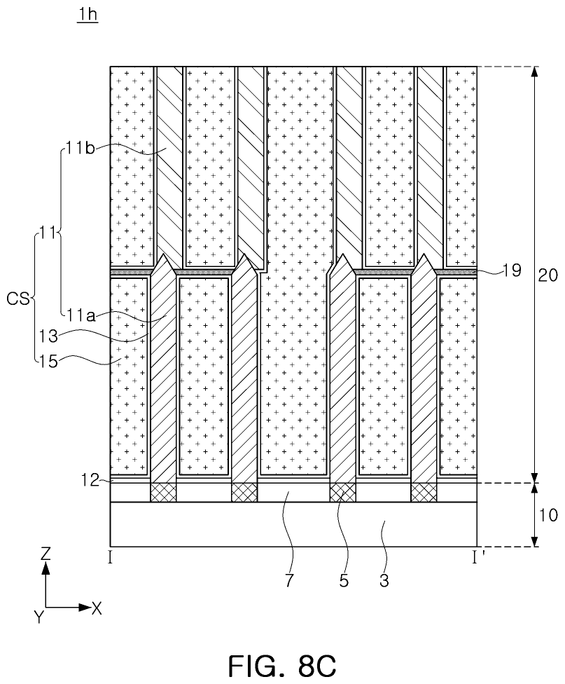

FIGS. 8A, 8B, 8C, 9 and 10 are respective cross-sectional views of semiconductor devices according to embodiments of the inventive concept taken along line I-I′ of FIG. 1.

Referring to FIG. 8A, within a semiconductor device 1f, the support layers (e.g., S1 and S2′) may have a structure different from that of FIG. 2. That is, the support layers may be vertically spaced apart with respect to the etch stop layer 19. In some embodiments, the etch stop layer 19 may be closely disposed on the uppermost support layer (e.g., S2′). In this case, the upper electrode 15 may further include a portion filling a gap between the etch stop layer 19 and the uppermost support layer, and the dielectric film 13 may further include a portion disposed between the first lower electrode 11a, the etch stop layer 19, and the portion of the upper electrode 15 between the etch stop layer 19 and the uppermost support layer. Accordingly, the lower surface of the etch stop layer 19 may contact the dielectric film 13. Since the etch stop layer 19 may serve as an additional support structure and/or an etch stop layer, an area of an electrode may be relatively increased by reducing a thickness of the uppermost support layer (e.g., the second support layer S2′). Therefore, semiconductor devices according to embodiments of the inventive concept may exhibit improved electrical characteristics, as well as an increased electrode area for the capacitor structure CS.

Referring to FIG. 8B, a semiconductor device 1g may include only a single support layer S1 that is vertically spaced apart from the etch stop layer 19. For example, as compared with the embodiment of FIG. 2, the second support layer S2 contact the etch stop layer 19 is omitted.

Referring to FIG. 8C, a semiconductor device 1h may entirely omit support layer(s). Accordingly, the semiconductor device 1h may exhibit high reliability and high productivity by using a double pillar storage node structure including first and second lower electrodes 11a and 11b and the etch stop layer 19, without the support layers S1 and S2 of FIG. 2.

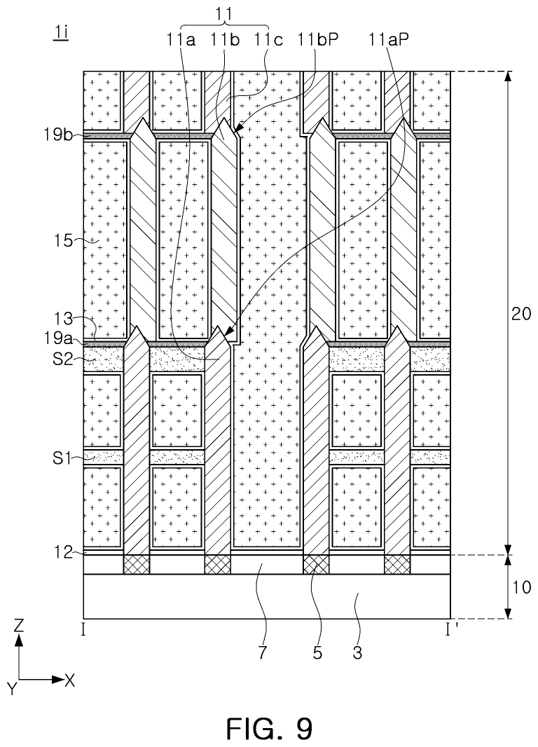

Referring to FIG. 9, within a semiconductor device 1i, the lower electrodes 11 may further include a third lower electrode 11c together with the first and second lower electrodes 11a and 11b. Here, the third lower electrode 11c may be vertically stacked (or disposed) on the second lower electrode 11b, and may be electrically connected to the second lower electrode 11b. Each of the plurality of lower electrodes 11 may have a multi-pillar storage node structure including the first to third lower electrodes 11a, 11b, and 11c.

The second lower electrode 11b may include the second protruding portion 11bP disposed at an upper end portion of the second lower electrode 11b and having a complex shape (e.g., a pointed pyramidal, fully conical or partially conical shape). The second protruding portion 11bP may have a structural shape that us substantially similar to that of the first protruding portion 11aP disposed at an upper end portion of the first lower electrode 11a.

The third lower electrode 11c may include at least one conductive material, and may be substantially similar to that of the first and/or second lower electrodes 11a and 11b.

However, consistent with the foregoing description, the third lower electrode 11c may be vertically misaligned with the second lower electrode 11b.

In some embodiments, the semiconductor device 1i may include a second etch stop layer 19b extending horizontally and substantially surrounding at least a portion of a side surface of the second protruding portion 11bP. The second etch stop layer 19b may be substantially similar that that of a first etch stop layer 19a substantially surrounding a side surface of the first protruding portion 11aP. For example, the second etch stop layer 19b may surround a portion of the second protruding portion 11bP while exposing a remaining portion of the second protruding portion 11bP, and the remaining portion may contact the third lower electrode 11c. In addition, the second etch stop layer 19b may perform a role of an etch stop layer or a role of adjusting a process margin distance in an etching process for forming the third lower electrode 11c, similarly to that described in FIG. 3.

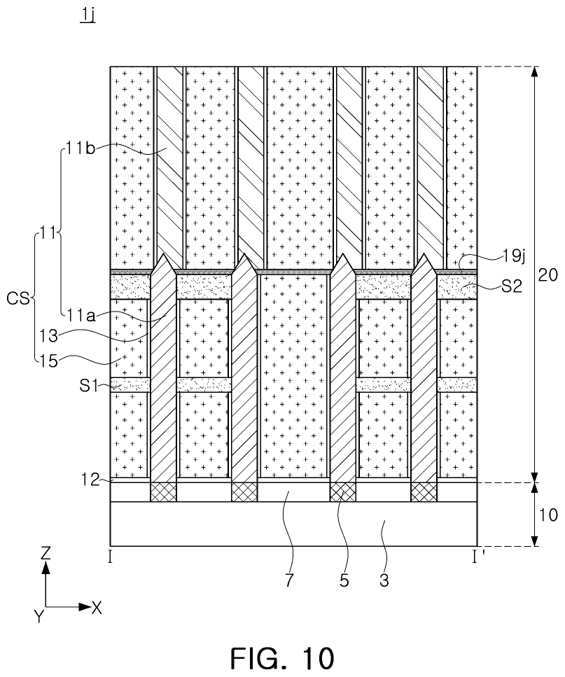

Referring to FIG. 10, a semiconductor device 1j may include an etch stop layer 19j different from the etch stop layer 19 of FIG. 2.

The etch stop layer 19j may include a portion formed on an upper surface of the uppermost support layer (e.g., S2). That is, the etch stop layer 19j may further include a filling portion extending horizontally on the uppermost support layer. Thus, the etch stop layer 19j may have a conformal thickness, except for the filling portion penetrated by the protruding portion 11aP of the first lower electrode 11a.

In some embodiments, upper and lower surfaces of the etch stop layer 19j and upper and lower surfaces of each of the support layers (e.g., S1 and S2) may not contact a dielectric film 13. Alternately, the dielectric film 13 may include portions extending onto the etch stop layer 19j and the upper and lower surfaces of the at least one support layer (S1 and S2), as illustrated in FIG. 2.

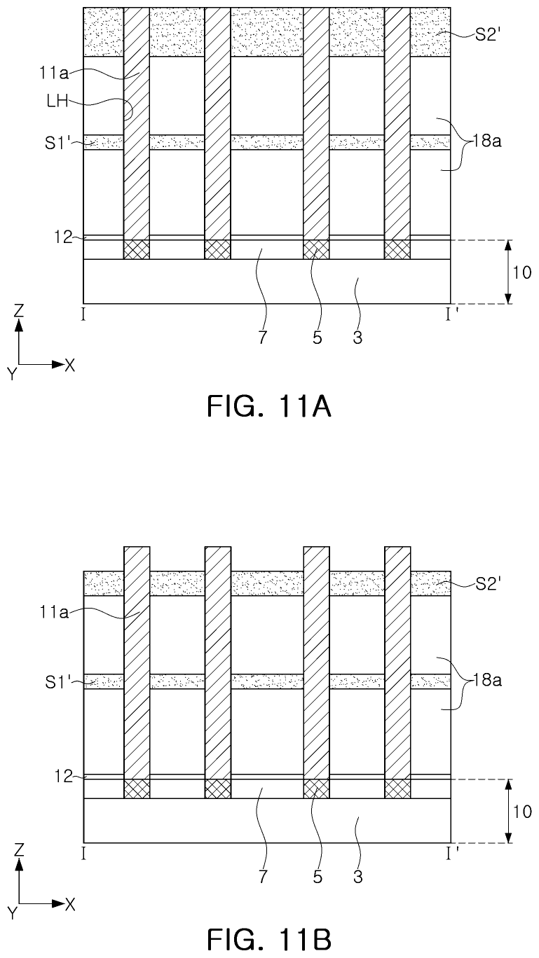

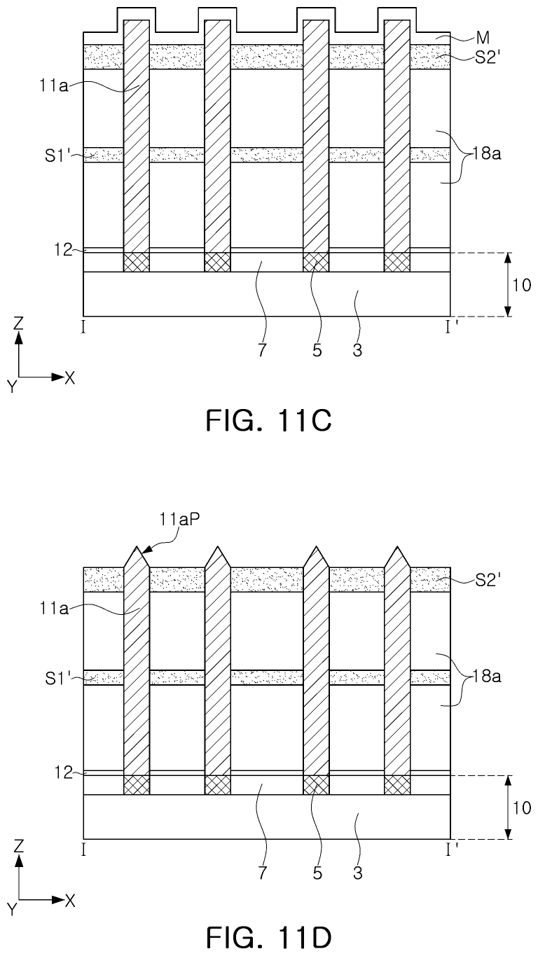

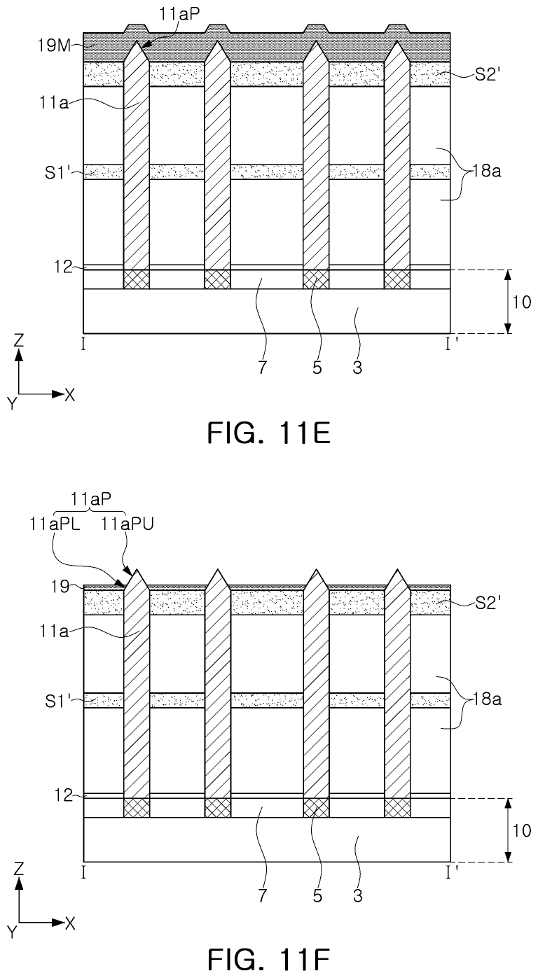

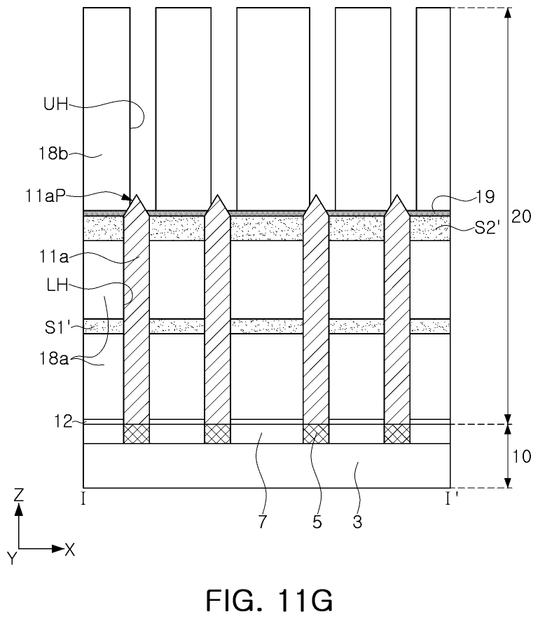

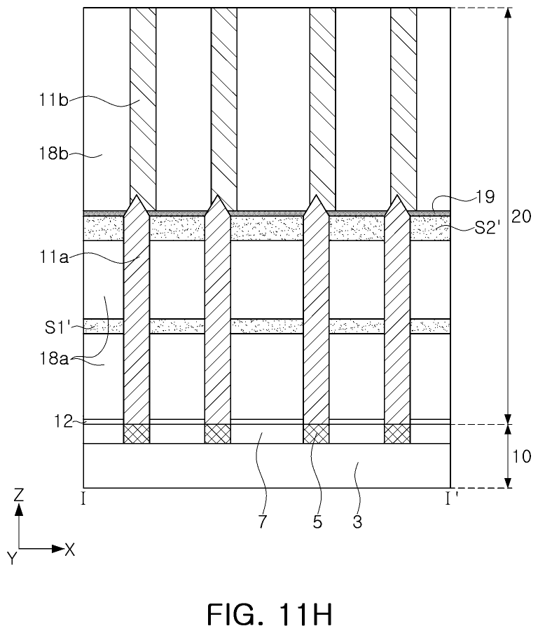

FIGS. 11A to 11H are related cross-sectional views illustrating in one example a method of manufacturing a semiconductor device according to embodiments of the inventive concept. Here, each of the FIGS. 11A to 11H is cross-section of semiconductor device 1 of FIG. 1 taken along line I-I′.

Referring to FIG. 11A, the lower structure 10 may be formed, lower molded layers 18a and preliminary support layers (e.g., S1′ and S2′) may be alternately stacked on the lower structure 10 to form a stack structure, and a first lower electrode 11a passing through the stack structure may be formed.

Here, active regions may be formed on a semiconductor substrate, a word line structure may be formed in trenches formed by removing a portion of the semiconductor substrate, and a bit line structure crossing the word line structure may be formed on the word line structure. The circuit structure 3 including a transistor may be formed, and the landing pads 5 electrically connected to the circuit structure 3 and the lower insulating layer 7 covering side surfaces of the landing pads 5 may be formed, to prepare the lower structure 10.

A buffer layer 12 may be conformally formed on the lower structure 10, and the lower molded layers 18a and the preliminary support layers may be alternately stacked on the buffer layer 12 in order to prepare the stack structure. The buffer layer 12 may include an insulating material having etch selectivity for the lower molded layers 18a under a specific etching condition, for example, at least one of silicon nitride (SiN) or silicon carbon nitride (SiCN). In some embodiments, the lower molded layers 18a and the preliminary support layers may each consist of two layers, but the number of preliminary support layers is not limited thereto. For example, the lower molded layers 18a may include at least one of silicon oxide and silicon nitride and the preliminary support layers may include at least one of silicon nitride and silicon carbonitride.

Next, a lower hole LH passing through the stack structure may be formed, a conductive material may be filled in the lower hole LH, and a chemical mechanical polishing (CMP) process or the like may be performed to form the first lower electrode 11a. The conductive material may be, for example, TiN. The lower hole LH may pass through the buffer layer 12 to expose the landing pads 5.

Referring to FIG. 11B, portions of the preliminary support layers may be removed to expose an upper end of the first lower electrode 11a.

For example, an uppermost preliminary support layer (e.g., S2′) may be removed to a predetermined depth by an etch-back process, to expose the upper end including portions of upper and side surfaces of the first lower electrode 11a. The upper portion including a portion may be exposed.

Referring to FIG. 11C, a mask layer M may be formed. That is, a deposition process may be performed to form the mask layer M covering the upper surface of the second preliminary support layer S2′ and the upper surface of the first lower electrode 11a.

Referring to FIG. 11D, the protruding portion 11aP may be formed on the first lower electrode 11a. That is, as an etching process is performed using the mask layer M, a portion of the upper end of the first lower electrode 11a may be removed to form the protruding portion 11aP having a geometrically “complex” (e.g., a pointed pyramidal, a fully conical or a partially conical) shape, as opposed to a “simple” shape, such as a flat surface. For example, the protruding portion 11aP may be formed with a conical shape according to a difference in etching speed in relation to the vertical and horizontal directions and/or a difference in thickness of the mask layer M in the vertical and horizontal directions in the etching process. The complex shape may be characterized by a plane area (or a width) that decreases in a direction away from the lower structure 10. The protruding portion 11aP having the complex shape may be exposed externally from the second preliminary support layer S2′.

During this etching process, the complex shape may be variously changed according to conditions of the etching process. In this regard, the etching process may include an isotropic etching process and/or an anisotropic etching process. For example, as a ratio of the anisotropic etching process increases, a convex conical shape like the one of FIG. 4A may be formed. As a ratio of the isotropic etching process increases, a concave conical shape may be formed. And various conical shapes may be formed by varying the ratio of isotropic etching and anisotropic etching.

Alternately, in some embodiments, a selective deposition process may be performed from the upper surface of the first lower electrode 11a having a surface, coplanar with the second preliminary support layer S2′, to form the protruding portion 11aP. In such cases, the etch-back process for the second preliminary support layer S2′ may be omitted. By the selective deposition process, a protruding portion 11aP protruding in the Z direction by being integrally connected to the first lower electrode 11a with a complex shape, wherein the specific geometry of the complex shape may vary with processing conditions associated with the selective deposition process.

Referring to FIG. 11E, a deposition process may be performed to form the preliminary etch stop layer 19M covering the second preliminary support layer S2′ and the protruding portion 11aP. The preliminary etch stop layer 19M may include at least one of silicon nitride (SiN), silicon carbonitride (SiCN), and silicon boronitride (SiBN). The preliminary etch stop layer 19M may include, for example, silicon boron nitride (SiBN).

Referring to FIG. 11F, an etch stop layer 19 may be formed by removing a portion of the preliminary etch stop layer 19M using a chemical mechanical polishing (CMP) process, an etch-back process, etc. The etch stop layer 19 may have a conformal thickness, and may expose a remaining portion externally while surrounding a portion of the protruding portion 11aP. The surrounded portion may be referred to as a lower region 11aPL of the protruding portion 11aP, and the remaining portion may be referred to as an upper region 11aPU of the protruding portion 11aP. Thus, using this approach, the semiconductor devices of FIG. 4A or 4B may be provided and may include the protruding portion 11aP having a pointed pyramidal shape.

Referring to FIG. 11G, an upper molded layer 18b and an upper hole UH passing through the upper molded layer 18b may be formed.

The upper molded layer 18b may be formed on the etch stop layer 19. The upper molded layer 18b may include at least one of silicon oxide and silicon nitride. The upper molded layer 18b may include material(s) substantially similar to material(s) of lower molded layers 18a.

An etching process may be performed to form the upper hole UH, to pass through the upper molded layer 18b to expose the protruding portion 11aP of the first lower electrode 11a. As the upper hole UH is formed by an etching process, separate from the lower hole LH, the upper hole UH may be misaligned with the lower hole LH. Accordingly, a central axis of the upper hole UH may be misaligned with a central axis of the lower hole LH. The upper hole UH may expose the etch stop layer 19. In some embodiments, a portion of the etch stop layer 19 may also be removed in an etching process for forming the upper hole UH together.

Referring to FIG. 11H, the second lower electrode 11b contacting the protruding portion 11aP may be formed.

As a conductive material fills the upper hole UH and a planarization process is performed, the second lower electrode 11b contacting the protruding portion 11aP may be formed.

Next, an opening passing through the upper molded layer 18b, the etch stop layer 19, the lower molded layers 18a, and the preliminary support layers (e.g., S1′ and S2′) may be formed using an etching mask, the lower molded layers 18a and the upper molded layer 18b exposed through the opening may be removed, and a dielectric film 13 and an upper electrode 15 may be formed. (See e.g., FIG. 2).

The opening may be formed by performing an etching process using the etching mask. During the etching process, portions of the preliminary support layers may be removed, and support layer (e.g., S1 and S2) connecting adjacent lower electrodes 11a and 11b may be formed. In some embodiments, the second preliminary support layer S2′ may be etched by an anisotropic etching process to form a second support layer S2, and portions of the lower molded layers 18a may be removed by an isotropic etching process before etching the first preliminary support layer. Similarly, after the first preliminary support layer S1′ is etched by an anisotropic etching process to form a first support layer S1, remaining portions of the lower molded layers 18a may be removed by an isotropic etching process.

Next, a dielectric material layer may be deposited to form the dielectric film 13. For example, the dielectric film 13 may include at least one of for example; an oxide, a nitride, a silicide, an oxynitride, and a silicide oxynitride, containing at least one of hafnium (Hf), aluminum (Al), zirconium (Zr), or lanthanum (La). In some embodiments, the dielectric film 13 may be provided as a plurality of layers. Next, the upper electrode may be formed by depositing a conductive material covering the dielectric film 13 and performing a patterning process. The conductive material may include at least one of for example; a semiconductor material such as doped polycrystalline silicon, a metal nitride such as titanium nitride (TiN), and a metal such as titanium (Ti), cobalt (Co), nickel (Ni), tungsten (W) and molybdenum (Mo).

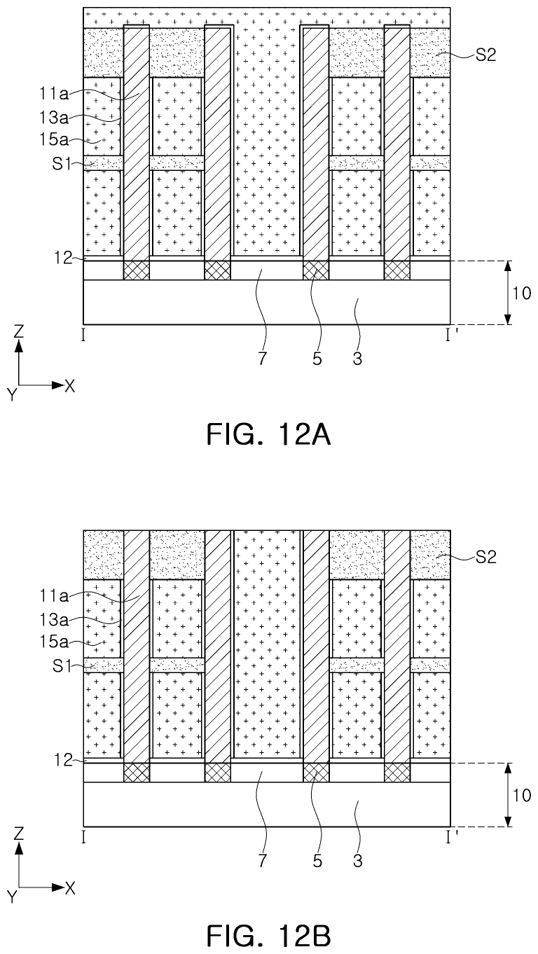

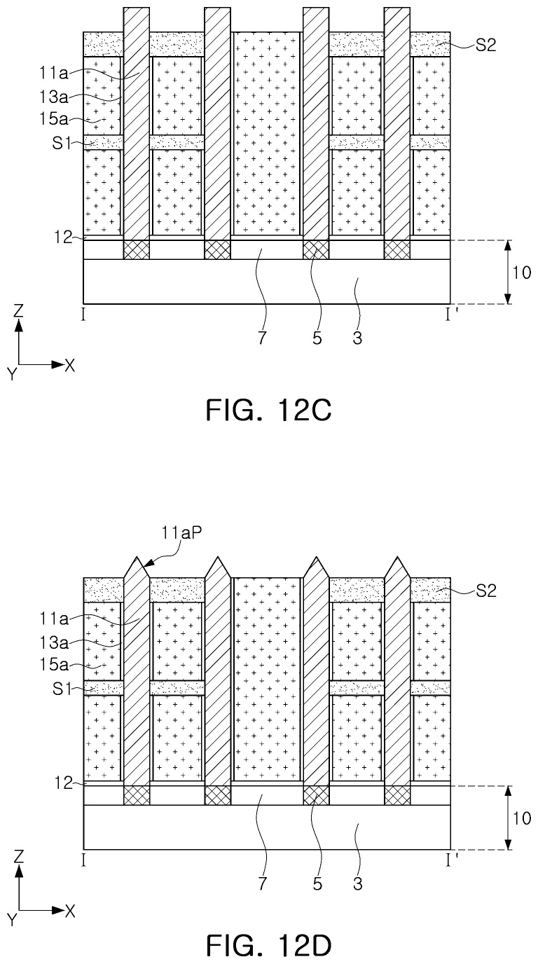

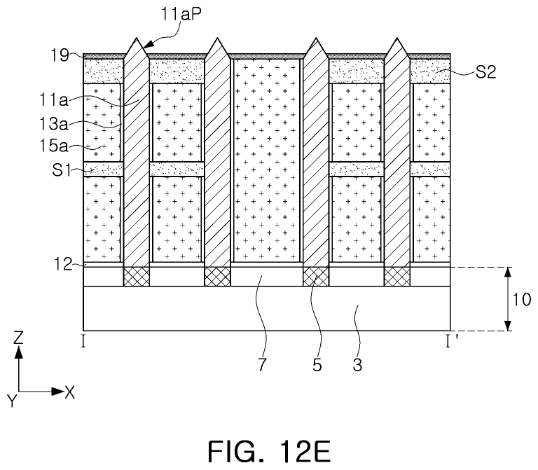

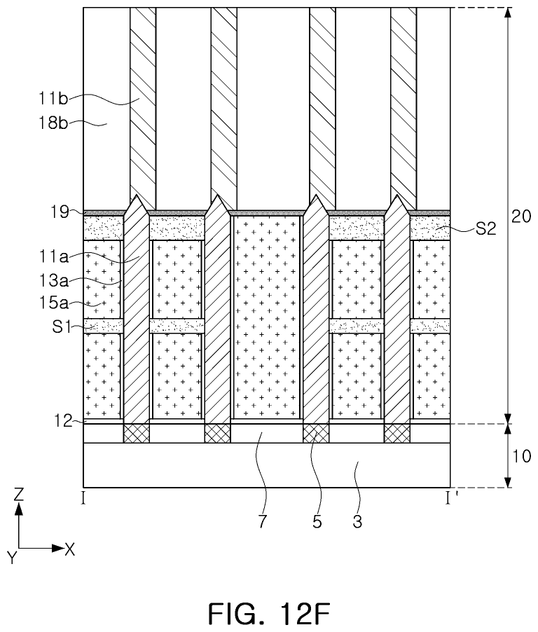

FIGS. 12A to 12F are related cross-sectional views illustrating in one example a method of manufacturing a semiconductor device according to embodiments of the inventive concept. Each of the FIGS. 12A to 12F is a cross-sections of the semiconductor device 1 of FIG. 1 taken along line I-I′.

Referring to FIG. 12A, the lower structure 10, the first lower electrode 11a, the support layers S1 and S2, a first dielectric film 13a and the first upper electrode 15a may be formed.

Similar to the description of FIG. 11A, the lower structure 10 may be formed, lower molded layers 18a and preliminary support layers S1′ and S2′ may be alternately stacked on the lower structure 10 to form a stack structure, and the first lower electrode 11a passing through the stack structure may be formed. Next, a lower opening passing through the stack structure, and the support layers S1 and S2 may be formed, the lower molded layers 18a exposed through the lower opening may be removed, and the first dielectric film 13a and the first upper electrode 15a may be formed.

In some embodiments, the first dielectric film 13a may be formed only on the first lower electrode 11a, but, otherwise, may also be formed on upper surfaces and/or lower surfaces of support layers S1 and S2 and an upper surface surface of the buffer layer 12.

Referring to FIG. 12B, the second support layer S2 and the first lower electrodec 11a may be exposed.

A planarization process including a chemical mechanical polishing process or the like may be performed to remove a portion of the first dielectric film 13a and a portion of the first upper electrode 15a, and an upper surface of the second support layer S2 and an upper surface of the first lower electrode 11a may be exposed.

Referring to FIG. 12C, a portion of the second support layer S2 may be removed to expose an upper end of the first lower electrode 11a.

Similar to that described with reference to FIG. 11B, the second support layer S2 may be removed by a predetermined depth in an etch-back process to expose the upper end including portions of upper and side surfaces of the first lower electrode 11a.

Referring to FIG. 12D, a protruding portion 11aP may be formed on the first lower electrode 11a.

Similar to the description of FIGS. 11C and 11D, a deposition process may be performed to form a mask layer covering the exposed upper end of the first lower electrode 11a, and an etching process may be performed using the mask layer to form the protruding portion 11aP having a conical shape.

Referring to FIG. 12E, similar to the description of FIGS. 11E and 11F, the etch stop layer 19 surrounding a portion of the protruding portion 11aP may be formed by depositing an insulating material such as silicon boron nitride (SiBN) and performing a chemical mechanical polishing process and an etch-back process.

Referring to FIG. 12F, an upper molded layer 18b and a second lower electrode 11b may be formed.

Similar to FIGS. 11G and 11H, the upper molded layer 18b may be formed on the etch stop layer 19, and an upper hole UH may be formed through the upper molded layer 18b to expose the protruding portion 11aP. The second lower electrode 11b contacting the protruding portion 11aP may be formed by filling a conductive material therein.

Next, a semiconductor device may be formed by selectively removing the upper molded layer 18b and sequentially forming a second dielectric film and a second upper electrode. In some embodiments, in this processing step, the second upper electrode may be also prepared after forming an opening through which the etch stop layer 19 is removed.

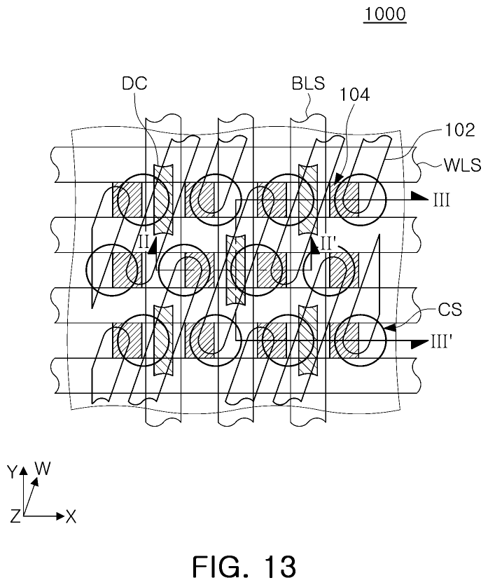

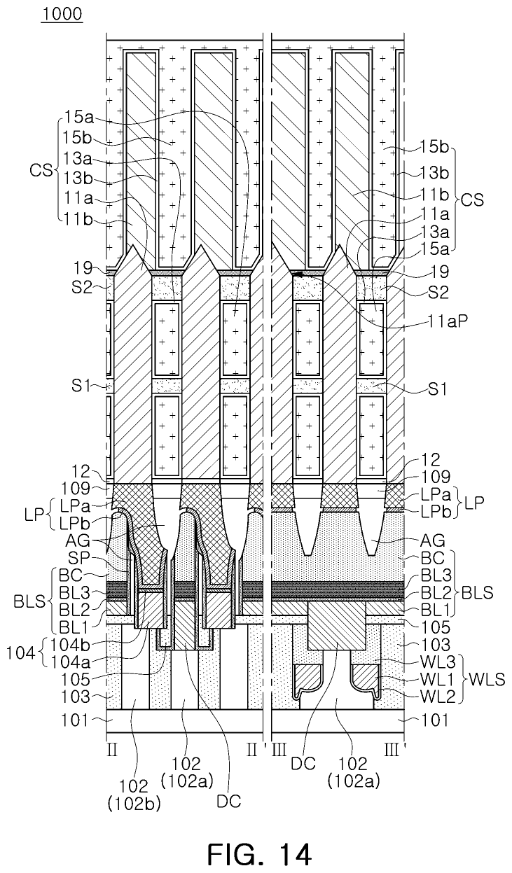

FIG. 13 is a plan view of a semiconductor device 1000 according to embodiments of the inventive concept, and FIG. 14 is a cross-sectional view of the semiconductor device 1000 taken along lines II-IP and of FIG. 13.

Referring to FIGS. 13 and 14, the semiconductor device 1000 may include a substrate 101 including active regions 102, a device isolation region 103 defining the active regions 102 in the substrate 101, a word line structure WLS buried and extending in the substrate 101 and including a word line WL1, a bit line structure BLS extending on the substrate 101 to cross the word line structure WLS and including bit lines BL1, BL2, and BL3, and a capacitor structure CS disposed on the bit line structure BLS.

The semiconductor device 1000 may include, for example, a DRAM cell array. For example, the bit line structure BLS may be connected to a first impurity region 102a of the active regions 102, the capacitor structure CS may be electrically connected to a second impurity region 102b of the active regions 102, and data may be stored in the capacitor structure CS. Since the capacitor structure CS has the same or similar characteristics as the capacitor structure CS of FIG. 2, an overlapped description thereof will be omitted.

The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may further include impurities. The substrate 101 may include a silicon substrate, a silicon-on-insulator (SOI) substrate, a germanium substrate, a germanium-on-insulator (GOI) substrate, a silicon-germanium substrate, or a substrate including an epitaxial layer.

The active regions 102 may be defined in substrate 101 by the device isolation region 103. The active region 102 may have a bar shape, and may be disposed in the substrate 101 in an island shape extending in one direction, for example, in the W direction. The active regions 102 may have the first and second impurity regions 102a and 102b at a predetermined depth from an upper surface of the substrate 101. The first and second impurity regions 102a and 102b may be spaced apart from each other. The first and second impurity regions 102a and 102b may be provided as source/drain regions of a transistor formed by the word line WL1. In embodiments, depths of the first and second impurity regions 102a and 120b in the source region and the drain region may be different from each other.

The device isolation region 103 may be formed by a shallow trench isolation (STI) process. The device isolation region 103 may electrically isolate the active regions 102 from each other while surrounding the active regions 102. The device isolation region 103 may be formed of an insulating material, for example, silicon oxide, silicon nitride, or a combination thereof. The device isolation region 103 may include a plurality of regions having different depths of lower ends according to a width of a trench in which the substrate 101 is etched.

The word line structure WLS may include a word line WL1, a gate dielectric layer WL2, and a gate capping layer WL3. The word line WL1 may be disposed to extend in the first horizontal direction (X) across the active regions 102. For example, a pair of adjacent word lines WL1 may be disposed to cross one active region 102. The word line WL1 may constitute a gate of a buried channel array transistor (BCAT) but is not limited thereto. According to embodiments, the word line WL1 may also be disposed on the upper surface of the substrate 101. The word line WL1 may be formed of at least one conductive material, such as for example; polycrystalline silicon (Si), titanium (Ti), titanium nitride (TiN), tantalum (Ta), tantalum nitride (TaN), tungsten (W), tungsten nitride (WN), and aluminum (Al). In some embodiments, the word line WL1 may have a multilayer structure formed of dissimilar materials.

The gate dielectric layer WL2 may conformally cover side and bottom surfaces of the word line WL1. The gate dielectric layer WL2 may include at least one of silicon oxide, silicon nitride, or silicon oxynitride. The gate dielectric layer WL2 may be, for example, a silicon oxide layer, or an insulating layer having a high dielectric constant.

The gate capping layer WL3 may be disposed on the word line WL1. The gate capping layer WL3 may be formed of an insulating material such as silicon nitride.

The bit line structure BLS may extend in a second horizontal direction, perpendicular to the word line WL1, for example, in the Y direction. The bit line structure BLS may include bit lines BL1, BL2, and BL3, and a bit line capping pattern BC on the bit lines BL1, BL2, and BL3.

The bit lines BL1, BL2, and BL3 may include a first conductive pattern BL1, a second conductive pattern BL2, and a third conductive pattern BL3, sequentially stacked. The first conductive pattern BL1 may include a semiconductor material such as polycrystalline silicon. The second conductive pattern BL2 may include a metal-semiconductor compound. The third conductive pattern BL3 may include a metal material such as titanium (Ti), tantalum (Ta), tungsten (W), or aluminum (Al). According to embodiments, the number and thicknesses of the conductive patterns constituting the bit lines may be variously changed.

The bit line capping pattern BC may be disposed on the bit lines BL1, BL2, and BL3. The bit line capping pattern BC may include an insulating material, for example, a silicon nitride layer. According to embodiments, the bit line capping pattern BC may include a plurality of capping pattern layers, and may be formed of different materials. For example, the number of capping patterns and/or a type of material constituting the bit line capping pattern BC may be variously changed according to embodiments.

In some embodiments, the bit line structure BLS may be disposed on the word line structure WLS, and a buffer insulating layer 105 may be disposed between the bit line structure BLS and the word line structure WLS.

In some embodiments, the semiconductor device 1000 may further include a bit line contact pattern DC passing through the first conductive pattern BL1 and contacting the first impurity regions 102a of the active regions 102. The bit line contact pattern DC may be electrically connected to the bit line structure BLS. A lower surface of the bit line contact pattern DC may be located on a higher level than an upper surface of the word line WL1. According to embodiments, the bit line contact pattern DC may be integrally formed with the first conductive pattern BL1.

In some embodiments, the semiconductor device 1000 may further include a lower electrode contact pattern 104, landing pads LP, and a lower insulating layer 109.

The lower electrode contact pattern 104 may be connected to one region of the active regions 102, for example, the second impurity region 102b. The lower electrode contact pattern 104 may be disposed between the bit lines BL1, BL2, and BL3, and between the word lines WL1. A lower surface of the lower electrode contact pattern 104 may be located on a lower level than the upper surface of the second impurity region 102b of the active region 102, and may be located on a higher level than the lower surface of the bit line contact pattern DC. The lower electrode contact pattern 104 may be insulated from the bit line contact pattern DC by a spacer SP. The spacer SP may include an insulating material such as silicon oxide, silicon nitride, or the like, may define an air gap AG, and may serve as a spacer, together with the air gap AG. A material and the number of layers constituting the spacer SP are not limited thereto, and may be variously changed. The lower electrode contact pattern 104 may be formed of a conductive material, for example, at least one of polycrystalline silicon (Si), titanium (Ti), titanium nitride (TiN), tantalum (Ta), tantalum nitride (TaN), tungsten (W), tungsten nitride (WN), or aluminum (Al). In some embodiments, the lower electrode contact pattern 104 may include a semiconductor layer 104a and a metal-semiconductor compound layer 104b on the semiconductor layer 104a. The metal semiconductor compound layer 104b may be a layer in which a portion of the semiconductor layer 104a is silicidated, and may include, for example, cobalt silicide (CoSi), titanium silicide (TiSi), nickel silicide (NiSi), tungsten silicide (WSi), or other metal silicides. According to embodiments, the number of layers and a material constituting the lower electrode contact pattern 104 may be variously changed.

The landing pads LP may be conductive patterns disposed on the lower electrode contact pattern 104. The landing pads LP may electrically connect the plurality of lower electrodes 11 and the lower electrode contact pattern 104. Each of the landing pads LP may be physically separated by the lower insulating layer 109. The landing pads LP may correspond to the landing pads 5 of FIG. 2, and the lower insulating layer 109 may correspond to the lower insulating layer 7 of FIG. 2.

In some embodiments, each of the landing pads LP may include a pad layer LPa and a barrier layer LPb. The pad layer LPa may include at least one conductive material such as for example; polycrystalline silicon (Si), titanium (Ti), tantalum (Ta), tungsten (W), ruthenium (Ru), copper (Cu), molybdenum (Mo), platinum (Pt), nickel (Ni), cobalt (Co), aluminum (Al), titanium nitride (TiN), tantalum nitride (TaN), and tungsten nitride (WN). The barrier layer LPb may include a metal nitride covering lower and side surfaces of the pad layer LPa, for example, at least one of titanium nitride (TiN), tantalum nitride (TaN), or tungsten nitride (WN).

A buffer layer 12, at least one support layer (S1 and S2), an etch stop layer 19, and a capacitor structure CS, disposed on the landing pads LP and the lower insulating layer 109, may have the same or similar features as those illustrated in FIG. 2. For example, a first lower electrode 11a of the capacitor structure CS may have a protruding portion 11aP having a conical shape.

According to embodiments, semiconductor devices may exhibit improved electrical characteristics by enhancing a contact area between first and second lower electrodes using a complex-shaped protruding portion and may further exhibit improved productivity by increasing a process margin distance between adjacent electrodes by manipulating processing conditions associated with an etch stop layer.

While embodiments have been illustrated and described above, it will be apparent to those skilled in the art that modifications and variations could be made without departing from the scope of the inventive concept as defined by the appended claims.

1. A semiconductor device comprising:
a lower structure;
lower electrodes on the lower structure, wherein each lower electrode includes a first lower electrode and a second lower electrode on the first lower electrode and electrically connected to the first lower electrode;
an upper electrode covering the lower electrodes; and
a dielectric film between the lower electrodes and the upper electrode,
wherein the first lower electrode includes a pillar portion, and a protruding portion on the pillar portion,
wherein the protruding portion extends upward from the pillar portion with a width gradually decreasing, and contacts the second lower electrode.

2. The semiconductor device of claim 1, wherein the protruding portion has a conical shape, and
wherein the conical shape includes a shape having a constantly inclined side surface, a shape having a region of which a lateral slope varies in a height direction, or a shape of which a lateral slope entirely varies in the height direction.

3. The semiconductor device of claim 1, wherein a width of the protruding portion gradually decreases as a distance from the lower structure increases.

4. The semiconductor device of claim 1, wherein at least a portion of an upper surface of the protruding portion contacts the second lower electrode.

5. The semiconductor device of claim 1, wherein at least a portion of the second lower electrode does not vertically overlap the first lower electrode.

6. The semiconductor device of claim 1, further comprising: an etch stop layer having a conformal thickness and extending horizontally to surround at least a portion of a side surface of the protruding portion.

7. The semiconductor device of claim 6, wherein a lower surface of the second lower electrode is covered by the protruding portion and the etch stop layer.

8. The semiconductor device of claim 6, wherein the etch stop layer comprises at least one of SiN, SiCN, or SiBN.

9. The semiconductor device of claim 1, wherein each of the plurality of lower electrodes further comprises a third lower electrode on the second lower electrode and electrically connected to the second lower electrode, and
wherein the second lower electrode is located on an upper end portion of the second lower electrode, and has a second protruding portion having a conical shape.

10. The semiconductor device of claim 9, wherein, in plan view, the third lower electrode has a portion misaligned with the second lower electrode.

11. A semiconductor device comprising:
a lower structure including a transistor; and
an upper structure on the lower structure and electrically connected to the transistor,
wherein the upper structure includes:
lower electrodes on the lower structure, wherein each lower electrodes includes a first lower electrode and a second lower electrode on the first lower electrode;
an upper electrode on the lower structure and covering the lower electrodes;
at least one support layer contacting the lower electrodes and extending in a horizontal direction, parallel to an upper surface of the lower structure;
an etch stop layer on an uppermost support layer among the at least one support layer and extending in the horizontal direction; and
a dielectric film between the lower electrodes and the upper electrode,
wherein the first lower electrode has a protruding portion having a conical shape, located in an upper end portion of the first lower electrode, and extending in a vertical direction, perpendicular to the upper surface of the lower structure, and
wherein a vertical central axis of the second lower electrode is misaligned with and in contact with a vertical central axis of the first lower electrode on the etch stop layer.

12. The semiconductor device of claim 11, wherein a thickness of the etch stop layer is thinner than a thickness of each of the at least one support layer.

13. The semiconductor device of claim 11, wherein the at least one support layer comprises SiN or SiCN, and
wherein the etch stop layer comprises at least one of SiN, SiCN, or SiBN.

14. The semiconductor device of claim 11, wherein the etch stop layer surrounds at least a portion of a side surface of the protruding portion.

15. The semiconductor device of claim 11, wherein the protruding portion decreases in planar area in a direction, away from a pillar portion of the first lower electrode in the vertical direction, and
wherein a lower end of the second lower electrode is located on a level higher than the pillar portion.

16. The semiconductor device of claim 11, wherein each of the at least one support layer is spaced apart from the etch stop layer.

17. The semiconductor device of claim 16, wherein the upper electrode comprises a portion filling between the at least one support layer and the etch stop layer.

18. A semiconductor device comprising:
a lower structure;
lower electrodes on the lower structure, wherein each lower electrode includes a first lower electrode and a second lower electrode on the first lower electrode and electrically connected to the first lower electrode;
an upper electrode on the lower structure;
an etch stop layer extending horizontally to contact the lower electrodes; and
a dielectric film between the lower electrodes and the upper electrode, wherein the first lower electrode includes a pillar portion and a protruding portion on the pillar portion and integrally connected to the pillar portion, the protruding portion has an inclined side surface, and
the etch stop layer contacts at least a portion of the inclined side surface of the protruding portion.

19. The semiconductor device of claim 18, wherein the etch stop layer exposes an upper region of the protruding portion while surrounding a lower region of the protruding portion, and
the upper region of the protruding portion contacts the second lower electrode.

20. The semiconductor device of claim 19, wherein a central axis of the second lower electrode laterally shifted from a central axis of the protruding portion.

21-27. (canceled)
